(19) United States
(12) Patent Application Publication
(10) Pub. No.: US 2019/0284691 A1
(43) Pub. Date: Sep. 19, 2019

(54) FILM FORMING METHOD AND FILM FORMING APPARATUS

(71) Applicant: TOKYO ELECTRON LIMITED, Tokyo (JP)

(72) Inventors: Shigehiro MIURA, Nirasaki City (JP); Takashi CHIBA, Oshu City (JP); Takehiro FUKADA, Oshu City (JP)

(21) Appl. No.: 16/357,285

(22) Filed: Mar. 18, 2019

(30) Foreign Application Priority Data
Mar. 19, 2018 (JP) 2018-051271

(51) Int. Cl. C23C 16/455; C23C 16/52; H01L 21/687; H01L 21/02; H01J 37/32

(52) U.S. Cl. CPC C23C 16/45536; C23C 16/45553; C23C 16/52; H01L 21/68764; H01J 2237/3321; H01L 21/02164; H01J 37/32449; H01J 37/32357; H01J 37/3211; H01L 21/0228

(57) ABSTRACT

There is provided a film forming method including: a modification process of modifying an oxide film formed on a substrate using oxygen radicals generated by a plasma source in a predetermined plasma processing region defined within a processing chamber; and an ignition preparation process of turning an internal state of the predetermined plasma processing region into a state in which plasma is likely to be ignited after the oxide film is formed on the substrate.

### CROSS-REFERENCE TO RELATED APPLICATION

This application is based upon and claims the benefit of priority from Japanese Patent Application No. 2018-051271, filed on Mar. 19, 2018, the entire contents of which are incorporated herein by reference.

### TECHNICAL FIELD

The present disclosure relates to a film forming method and a film forming apparatus.

### BACKGROUND

Conventionally, as a method for forming a thin film such as a silicon oxide film on a substrate such as a semiconductor wafer, an atomic layer deposition (ALD) is used where multiple types of processing gases reacting with each other are sequentially supplied onto the front surface of the substrate to deposit an atomic layer of reaction product. For example, a rotary table type ALD-based film forming apparatus is known where a rotary table on which a substrate is mounted is rotated to perform an ALD-based film formation. Specifically, in such a film forming apparatus, five or six wafers are mounted on the rotary table in the circumferential direction, and a raw material gas supply part or an antenna for turning a gas into plasma is disposed to face the trajectory of the wafers moving (revolving) with the rotation of the rotary table.

In forming a high-quality silicon oxide film (SiO₂ film) using an ALD-based film forming apparatus, a raw material gas adsorption region, an oxidation region, and a plasma processing region are provided in the rotational direction of the rotary table. In addition, the high-quality silicon oxide film is formed by supplying a silicon-containing gas such as 3DMA (tris (dimethylamino) silane), an organic aminosilane gas or the like to the raw material gas adsorption region, supplying an oxidizing gas such as ozone to the oxidation region, supplying plasma composed of a mixed gas of argon, oxygen, hydrogen and the like to the plasma processing region, and causing the wafers to sequentially pass through the raw material gas adsorption region, the oxidation region, and the plasma processing region at high speed with the rotation of the rotary table. In such a film forming method, one layer of Si source adsorbed onto each wafer in the raw material gas adsorption region is oxidized in the oxidation region to deposit a molecular layer of SiO₂. The molecular layer of SiO₂ thus deposited is modified by the plasma in the plasma processing region. Then, by continuously rotating the rotary table, a cycle including a series of processes as described above is repeated again, so that the silicon oxide film is formed. In the conventional film forming apparatus, it is possible to perform a high-speed ALD-based film formation that performs modification using plasma for each layer at, for example, the rate of about 100 to 300 times per minute.

However, in the conventional ALD-based film forming apparatus, each of the raw material gas adsorption region, the oxidation region, and the plasma processing region is not completely separated from each other by a wall or the like, but is separated by a pressure wall using a separation gas. Specifically, separation regions having a narrow space between a surface protruding downwards from a ceiling surface of a processing chamber and an upper surface of the rotary table are formed between the raw material gas adsorption region and the oxidation region and between the plasma processing region and the raw material gas adsorption region, respectively. A separation gas is supplied toward the rotary table through the vicinity of the center of each separation region such that high-pressure walls are formed by the separation gas. In this way, the regions are separated from each other. Therefore, the conventional apparatus has a configuration in which a plurality of processing regions is formed inside a single processing chamber with the pressure wall interposed between the processing regions. This makes it difficult to perform pressure control for setting the raw material gas adsorption region as a high-pressure zone in the level of several Torr, which is advantageous for adsorption, and for setting the plasma processing region as a low-pressure zone in the level of several 10 mTorr, which is advantageous for plasma discharge and modification. In practice, the plasma processing region is also often used in a high-pressure zone of 1 Torr or higher. In the high-pressure zone of 1 Torr or higher, high-density plasma such as inductively coupled plasma (ICP) often has a disadvantageous effect on discharge. In addition, a Faraday shield is installed as a countermeasure for charge-up damage to a device wafer due to plasma and inductively coupled plasma mainly composed of magnetic field components is used by cutting the electric field components. In this case, high-pressure discharge becomes further difficult.

For this reason, the ignition time of plasma becomes long when a processed wafer is unloaded from the processing chamber and a subsequent wafer is loaded into the processing chamber to start the processing. Such an ignition delay results in a degradation of throughput, which deteriorates productivity. In addition, even in the case of a film forming apparatus other than the rotary table type ALD-based film forming apparatus, the same phenomenon may occur when the discharge environment in the plasma processing region is not good.

### SUMMARY

Some embodiments of the present disclosure provide a film forming method and film forming apparatus, which are capable of performing plasma ignition in a stable manner while preventing plasma ignition delay when a substrate processed inside a processing chamber is replaced with a new one and an operation of the film forming apparatus is initiated, and capable of making plasma ignition times between respective operations substantially constant.

According to one embodiment of the present disclosure, there is provided a film forming method including: a modification process of modifying an oxide film formed on a substrate using oxygen radicals generated by a plasma source in a predetermined plasma processing region defined within a processing chamber; and an ignition preparation process of turning an internal state of the predetermined plasma processing region into a state in which plasma is likely to be ignited after the oxide film is formed on the substrate.

According to another embodiment of the present disclosure, there is provided a film forming apparatus including: a processing chamber; a rotary table provided inside the processing chamber and configured to mount a substrate on an upper surface of the rotary table along a circumferential direction; a raw material gas supply part configured to supply a raw material gas to the rotary table; an oxidizing gas supply part provided at a downstream side in a rotational direction of the rotary table and configured to supply an oxidizing gas to the rotary table; a plasma-processing gas supply part provided at a downstream side in the rotational direction of the rotary table and configured to supply a plasma-processing gas to the rotary table; a plasma processing region defined to surround the plasma-processing gas supply part from upper and lateral sides of the plasma-processing gas supply part; a plasma source configured to generate plasma within the plasma processing region; and a controller configured to control the raw material gas supply part, the oxidizing gas supply part, the plasma-processing gas supply part and the plasma source to execute a control, wherein the control alternately performs a film formation process of forming an oxide film on the substrate by controlling the raw material gas supply part to supply the raw material gas and controlling the oxidizing gas supply part to supply the oxidizing gas while rotating the rotary table, and a modification process of modifying the oxide film by driving the plasma source and controlling the plasma-processing gas supply part to supply the plasma-processing gas including an oxidizing gas; and after the film formation process and the modification process, performing a plasma ignition preparation process of stopping the supply of the raw material gas and the supply of the oxidizing gas, and controlling the plasma-processing gas supply part to stop supplying an oxygen gas while driving the plasma source and to supply a hydrogen atom-containing gas.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a schematic vertical cross-sectional view showing an example of a film forming apparatus according to an embodiment of the present disclosure.

FIG. 2 is a schematic plan view showing the example of the film forming apparatus according to the embodiment.

FIG. 3 is a cross-sectional view from a separation region to another separation region via a first processing region.

FIG. 4 is a vertical cross-sectional view showing an example of the plasma source in the present embodiment.

FIG. 5 is an exploded perspective view showing an example of the plasma source in the present embodiment.

FIG. 6 is a perspective view of an example of a housing provided in the plasma source according to the present embodiment.

FIG. 7 is a vertical cross-sectional view of a vacuum container cut in a rotational direction of a rotary table.

FIG. 8 is an enlarged perspective view illustrating a plasma-processing gas nozzle provided in a plasma processing region.

FIG. 9 is a plan view of an example of the plasma source.

FIG. 10 is a perspective view illustrating a portion of a Faraday shield provided in the plasma source.

FIG. 11 is a diagram showing ionization electron energy of an argon gas.

FIG. 12 is a diagram showing ionization electron energy of an oxygen gas.

FIG. 13 is a process flowchart of a film forming method according to an embodiment.

FIGS. 14A and 14B are tables showing implementation conditions and results of Examples 1 to 4 in which the film forming method according to the present embodiment was implemented.

### DETAILED DESCRIPTION

Hereinafter, modes for carrying out the present disclosure will be described with reference to the figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Film Forming Apparatus]

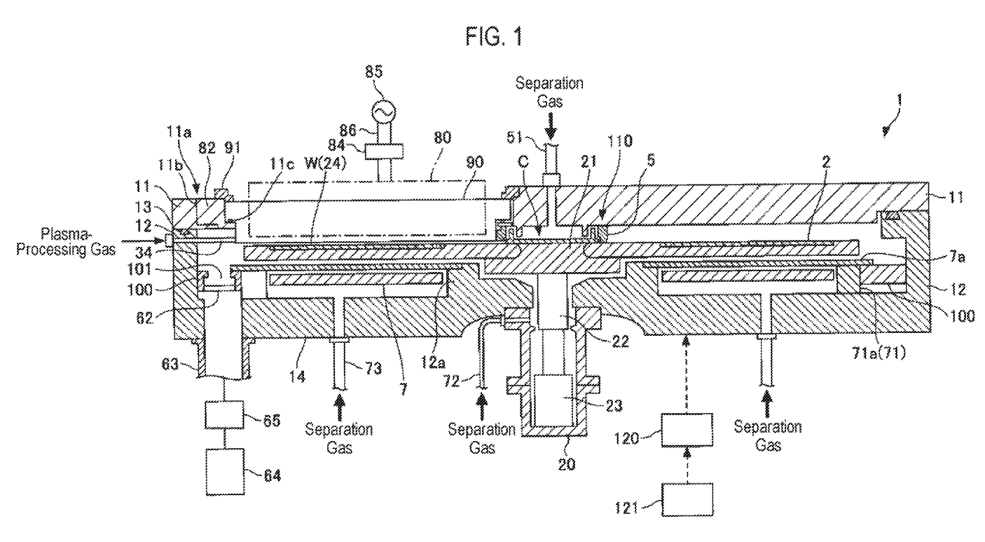

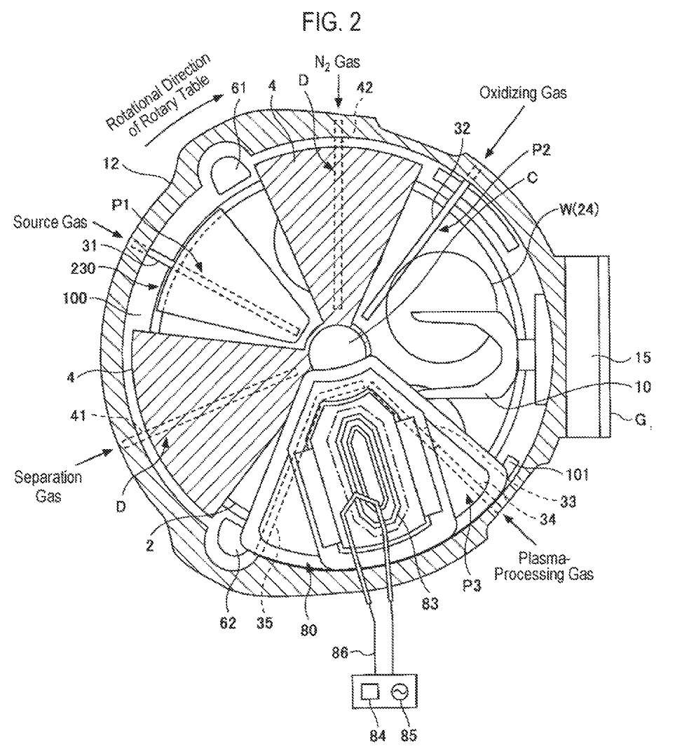

FIG. 1 is a schematic vertical cross-sectional view showing an example of a film forming apparatus according to an embodiment of the present disclosure. FIG. 2 is a schematic plan view showing the example of the film forming apparatus according to this embodiment. For the sake of convenience in description, the illustration of a ceiling plate 11 is omitted in FIG. 2.

As illustrated in FIG. 1, the film forming apparatus according to the present embodiment includes a vacuum container 1 having a substantially-circular planar shape, and a rotary table 2 provided inside the vacuum container 1 and having a rotational center coinciding with the center of the vacuum container 1. The rotary table 2 is configured to revolve wafers W.

The vacuum container 1 is a processing chamber in which the wafers W are accommodated and film formation is performed on front surfaces of the wafers W to deposit a thin film on each front surface of the wafers W. The vacuum container 1 includes the ceiling plate (ceiling part) 11 provided at a position facing recesses 24 (to be described later) of the rotary table 2, and a container body 12. In addition, a ring-shaped seal member 13 is provided on a peripheral portion of an upper surface of the container body 12. The ceiling plate 11 is configured to be detachable from the container body 12. A diameter (inner diameter dimension) of the vacuum container 1 in a plan view is not particularly limited, but may be set to about 1,100 mm.

A separation gas supply pipe 51 is connected to the central portion of the upper surface of the vacuum container 1. The separation gas supply pipe 51 supplies a separation gas to suppress different processing gases from being mixed with each other in an internal central region C of the vacuum container 1.

The rotary table 2 is fixed to a substantially-cylindrical core part 21 at the central portion thereof. The rotary table 2 is configured to be rotatable around a vertical axis by a drive part 23 clockwise in the example illustrated in FIG. 2 while being supported by a rotary shaft 22 connected to a lower surface of the core part 21 and extending in the vertical direction. The diameter dimension of the rotary table 2 is not particularly limited, but may be set to about 1,000 mm.

The rotary shaft 22 and the drive part 23 are accommodated in a case body 20. The case body 20 has a flange portion formed on the upper surface thereof, which is hermetically attached to a lower surface of a bottom portion 14 of the vacuum container 1. A purge gas supply pipe 72 is connected to the case body 20 to supply an Ar gas or the like as a purge gas (separation gas) to a region below the rotary table 2.

In the bottom portion 14 of the vacuum container 1, a portion located at the side of an outer periphery of the core part 21 is formed in a ring shape so as to be close to the rotary table 2 from below. The portion is referred to as a protruded portion 12a.

In the front surface of the rotary table 2, there are formed circular recesses 24 as substrate mounting regions in each of which the wafer W having a diameter dimension of, for example, 300 mm, is received. The recesses 24 are formed at multiple locations, for example, five locations in the rotational direction of the rotary table 2. Each of the recesses 24 has a diameter slightly (specifically, about 1 mm to 4 mm) larger diameter than the wafer W. In addition, the depth of the recess 24 is substantially equal to the thickness of the wafer W or larger than the thickness of the wafer W. Therefore, when the wafer W is accommodated in the recess 24, the front surface of the wafer W and a flat front surface region of the rotary table 2 on which no wafer W is mounted may have the same height. Alternatively, the front surface of the wafer W may be slightly lower than the front surface of the rotary table 2. Further, through-holes (not shown) through which three lift pins for moving the wafer W up and down while pushing a back surface of the wafer W upward from below penetrate, are formed in a bottom surface of the recess 24.

As illustrated in FIG. 2, a first processing region P1, a second processing region P2, and a third processing region P3 are provided in a mutually spaced-apart relationship along the rotational direction of the rotary table 2. At positions above the rotary table 2 through which the recesses 24 pass, a plurality of (e.g., seven) gas nozzles 31, 32, 33, 34, 35, 41, and 42 made of, for example, quartz, are radially arranged in a mutually spaced-apart relationship along the circumferential direction of the vacuum container 1. Each of the gas nozzles 31, 32, 33, 34, 35, 41, and 42 is arranged between the rotary table 2 and the ceiling plate 11. For example, each of the gas nozzles 31, 32, 33, 34, 41, and 42 is installed to horizontally extend from an outer peripheral wall of the vacuum container 1 toward the central region C while facing the rotary table 2. Meanwhile, the gas nozzle 35 extends from the outer peripheral wall of the vacuum container 1 toward the central region C, and then bent linearly toward the central region C in the counterclockwise direction (the direction opposite the rotational direction of the rotary table 2). In the example illustrated in FIG. 2, the plasma-processing gas nozzles 33 and 34, the plasma-processing gas nozzle 35, the separation gas nozzle 41, the first processing gas nozzle 31, the separation gas nozzle 42, and the second processing gas nozzle 32 are arranged in this order in the clockwise direction (the rotational direction of the rotary table 2) from a transfer port 15 (to be described later). A gas supplied from the second processing gas nozzle 32 is often the same quality as gases supplied from the plasma-processing gas nozzles 33 to 35. However, when the amount of the gases supplied from the plasma-processing gas nozzles 33 to 35 is sufficient, the second processing gas nozzle 32 may be omitted.

Further, a single plasma-processing gas nozzle may be substituted for the plasma-processing gas nozzles 33 to 35. In this case, for example, like the second processing gas nozzle 32, the single plasma-processing gas nozzle may be installed to extend from the outer peripheral wall of the vacuum container 1 toward the central region C.

The first processing gas nozzle 31 constitutes a first processing gas supply part. The second processing gas nozzle 32 constitutes a second processing gas supply part. Further, each of the plasma-processing gas nozzles 33 to 35 constitutes a plasma-processing gas supply part. Each of the separation gas nozzles 41 and 42 forms a separation gas supply part.

The gas nozzles 31, 32, 33, 34, 35, 41, and 42 are coupled to gas supply sources (not illustrated) through flow rate control valves, respectively.

A plurality of gas ejection holes 36 through which the respective gases are ejected is formed in a lower surface of (surface facing the rotary table 2) of each of the gas nozzles 31, 32, 33, 34, 35, 41, and 42 along the radial direction of the rotary table 2, for example, at equal intervals. A separation distance between a lower end of each of the gas nozzles 31, 32, 33, 34, 35, 41, and 42 and the front surface of the rotary table 2 is, for example, about 1 to 5 mm.

A region below the first processing gas nozzle 31 constitutes the first processing region P1 in which a raw material gas is adsorbed by the wafer W. A region below the second processing gas nozzle 32 constitutes the second processing region P2 in which an oxidizing gas capable of producing an oxide by oxidizing the raw material gas is supplied to the wafer W. In addition, a region below the plasma-processing gas nozzles 33 to 35 constitutes the third processing region P3 in which a modification process is performed with respect to a film formed on the wafer W.

The first processing gas nozzle 31 is a nozzle for supplying the raw material gas (precursor) containing a raw material as a main component of the film. For example, in a case of forming a silicon oxide film, the first processing gas nozzle 31 may supply a silicon-containing gas. In a case of forming a metal oxide film, the first processing gas nozzle 31 may supply a metal-containing gas. Therefore, the first processing gas nozzle 31 may be referred to as a raw material gas nozzle 31. In addition, since the first processing region P1 is a region in which the raw material gas is adsorbed by the wafer W, the first processing region P1 is also referred to as a raw material gas adsorption region P1.

Similarly, the second processing gas nozzle 32 supplies the oxidizing gas such as oxygen, ozone, water, or hydrogen peroxide toward the wafer W to form an oxide film. Thus, the second processing gas nozzle 32 is also referred to as an oxidizing gas nozzle 32. In addition, the second processing region P2 is a region where the oxidizing gas is supplied to the wafer W onto which the raw material gas is adsorbed in the first processing region P1 to oxidize the raw material gas. Thus, the second processing region P2 is also referred to as an oxidation region P2. In the oxidation region P2, a molecular layer of the oxide film is deposited on the wafer W.

The third processing region P3 is a region in which the molecular layer of the oxide film formed in the second processing region P2 is plasma-processed to modify the oxide film. Thus, the third processing region P3 is also referred to as a plasma processing region P3. In this embodiment, the oxide film is formed. Thus, the plasma-processing gas supplied from each of the plasma-processing gas nozzles 33 to 35 may be a gas containing at least an oxygen gas.

The separation gas nozzles 41 and 42 are provided to form separation regions D for separating the first processing region P1 and the third processing region P3 from each other and for separating the second processing region P2 and the first processing region P1 from each other, respectively. The separation gas supplied from the separation gas nozzles 41 and 42 is an inert gas such as nitrogen, or a noble gas such as helium, argon or the like. The separation gas also functions as a purge gas. Thus, the separation gas is also referred to as a purge gas, and the separation gas nozzles 41 and 42 are also referred to as purge gas nozzles 41 and 42. In addition, no separation region D is provided between the second processing region P2 and the third processing region P3. The reason for this is as follows. The mixed gas supplied in the third processing region P3 includes the oxygen gas. Both the oxidizing gas supplied in the second processing region P2 and the oxygen gas of the mixed gas supplied in the third processing region P3 includes oxygen atoms, thus functioning as an oxidizing agent. Thus, it is not necessary to separate the second processing region P2 and the third processing region P3 using the separation gas.

The plasma-processing gas nozzles 33 to 35 are structured to supply gases to different regions on the rotary table 2. Thus, the plasma-processing gas nozzles 33 to 35 may supply the mixed gas in a state where a flow rate ratio of each gas component of the mixed gas is made different for each region such that the modification process is carried out uniformly as a whole.

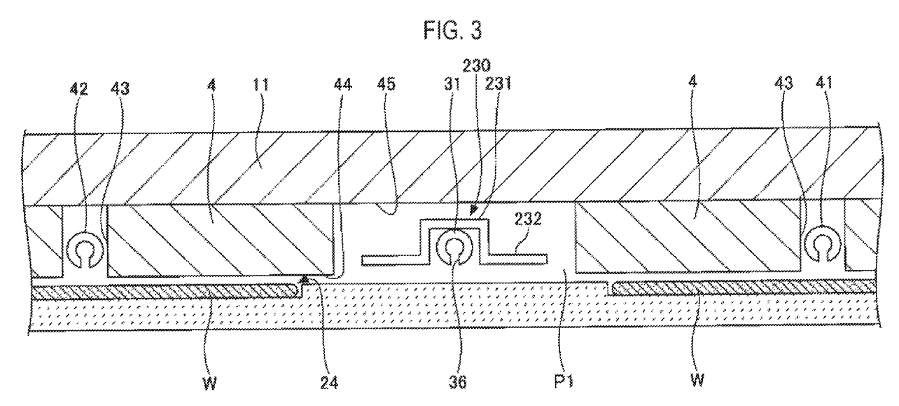

FIG. 3 is a cross-sectional view of the film forming apparatus according to this embodiment, which is taken along the concentric circle of the rotary table, and shows a cross-sectional area ranging from one separation region D to the other separation region D via the first processing region P1.

In each of the separation regions D, substantially fan-shaped convex portions 4 are provided on the ceiling plate 11 of the vacuum container 1. The convex portions 4 are attached to a rear surface of the ceiling plate 11. Inside the vacuum container 1, there are formed flat lower ceiling surfaces 44 (first ceiling surfaces) which are lower surfaces of the convex portions 4, and upper ceiling surfaces 45 (second ceiling surfaces) which are located higher than the lower ceiling surfaces 44 at both sides of the lower ceiling surfaces 44 in the circumferential direction.

As illustrated in FIG. 2, each of the convex portions 4 forming the lower ceiling surfaces 44 has a fan-like planar shape in which the apex portion is cut in an arc shape. In addition, at the center of each convex portion 4 in the circumferential direction, a groove 43 is formed so as to extend in the radial direction. The separation gas nozzle 41 (42) is accommodated in the groove 43. In order to prevent the processing gases from being mixed with each other, the peripheral portion of the convex portion 4 (a portion facing an inner periphery of the vacuum container 1) is bent in an L-like shape to face an outer end surface of the rotary table 2 while being spaced slightly from the container body 12.

A nozzle cover 230 is provided above the first processing gas nozzle 31 such that a first processing gas is allowed to flow along the wafer W and the separation gas is allowed to pass through the side of the ceiling plate 11 of the vacuum container 1 while bypassing the vicinity of the wafer W. As illustrated in FIG. 3, the nozzle cover 230 includes a substantially box-shaped cover body 231 having an opened lower surface to accommodate the first processing gas nozzle 31 therein, and plate-shaped rectifying plates 232 which are respectively connected to both sides of the opened lower surface of the cover body 231 so as to be connected to upstream and downstream sides of the rotary table 2 in the rotational direction of the rotary table 2. A sidewall surface of the cover body 231 at a rotational central side of the rotary table 2 extends toward the rotary table 2 so as to face a leading end portion of the first processing gas nozzle 31. A sidewall surface of the cover body 231 at an outer peripheral side of the rotary table 2 is cut out so as not to interfere with the first processing gas nozzle 31. The nozzle cover 230 is not essential and may be provided as necessary.

As illustrated in FIG. 2, a plasma source 80 is provided above the plasma-processing gas nozzles 33 to 35 to turn the plasma-processing gas ejected into the vacuum container 1 into plasma.

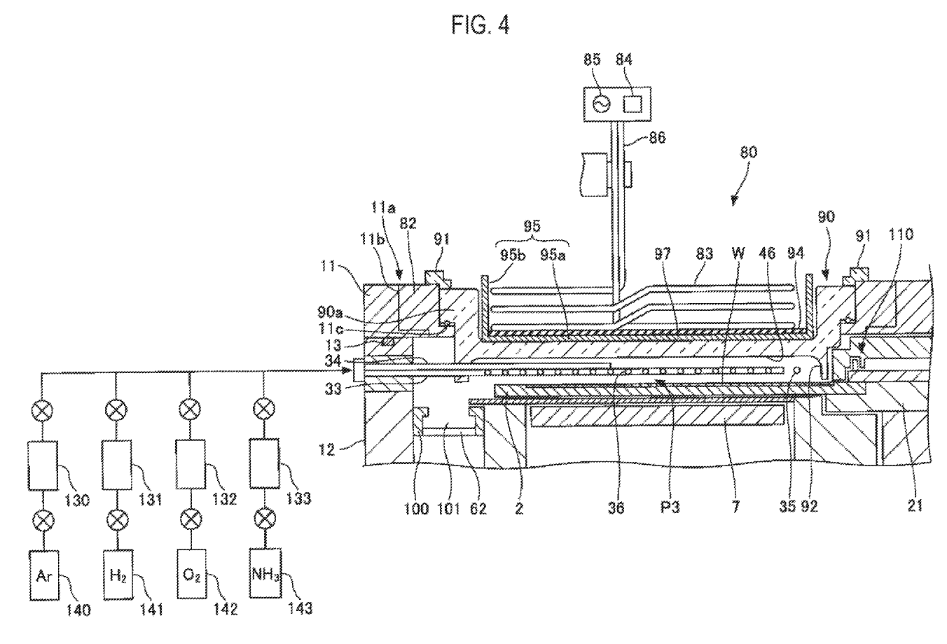

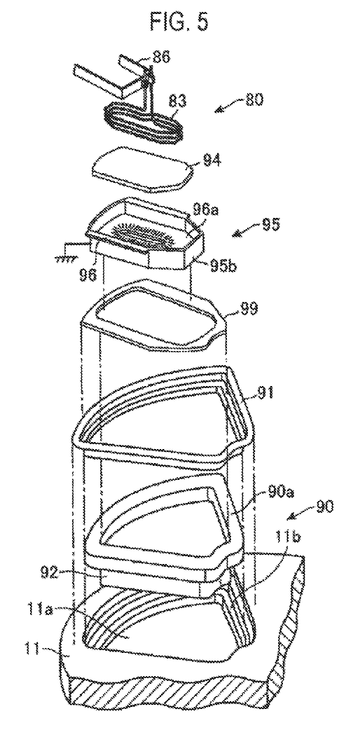

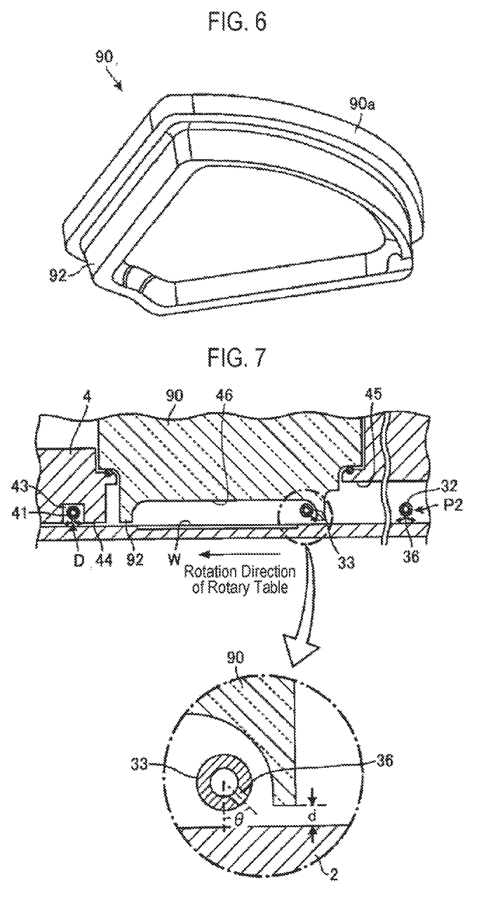

FIG. 4 is a vertical cross-sectional view of an example of the plasma source 80 according to this embodiment. FIG. 5 is an exploded perspective view of the example of the plasma source 80 according to this embodiment. FIG. 6 is a perspective view illustrating an example of a housing provided in the plasma source 80 according to this embodiment.

The plasma source 80 is constituted by winding an antenna 83 formed of a metal wire or the like in a coil shape around a vertical axis, for example, in triplicate. The plasma source 80 is disposed to surround a band-shaped region extending in the radial direction of the rotary table 2 and to stride over a diameter portion of the wafer W on the rotary table 2 as viewed from the top.

The antenna 83 is coupled to a high frequency power supply 85 having a frequency of, for example, 13.56 MHz, and an output power of, for example, 5,000 W, via a matching device 84. Further, the antenna 83 is provided so as to be hermetically isolated from an inner region of the vacuum container 1. In FIGS. 4 and 5, a connection electrode 86 is provided to electrically connect the antenna 83 to the matching device 84 and the high frequency power supply 85.

In some embodiments, the antenna 83 may have a vertically-bendable configuration, a vertically-movable mechanism capable of vertically bending the antenna 83 in an automatic manner, or a vertically-movable mechanism capable of vertically moving through the central position of the rotary table 2 as necessary. In FIG. 4, the illustration of such configuration and mechanisms is omitted.

As illustrated in FIGS. 4 and 5, in the ceiling plate 11, an opening 11a is formed in a fan-like planar shape above the plasma-processing gas nozzles 33 to 35,

As illustrated in FIG. 4, an annular member 82 is hermetically provided in the opening 11a along an edge portion of the opening 11a. A housing 90 (to be described later) is hermetically installed on an inner peripheral surface 11b of the annular member 82. That is to say, the annular member 82 is installed such that the outer periphery of the annular member 82 is brought into hermetic contact with the inner peripheral surface 11b of the opening 11a of the ceiling plate 11 and the inner periphery thereof is brought into hermetic contact with a flange portion 90a (to be described later) of the housing 90. The housing 90 made from a derivative such as quartz is provided in the opening 11a via the annular member 82 such that the antenna 83 is located below the ceiling plate 11. A lower surface of the housing 90 constitutes a ceiling surface 46 of the plasma processing region P3.

As illustrated in FIG. 6, an upper peripheral portion of the housing 90 constitutes the flange portion 90a extending horizontally in a flange shape in the circumferential direction. As viewed from the top, the central portion of the housing 90 is concavely formed toward the inner region of the vacuum container 1 located below the housing 90.

In the case where the wafer W is positioned below the housing 90, the housing 90 is disposed to stride over the diameter portion of the wafer W in the diametrical direction of the rotary table 2. In addition, a seal member 11c such as an O-ring is provided between the annular member 82 and the flange portion 90a (see FIG. 4).

An internal atmosphere of the vacuum container 1 is set to be airtight by the annular member 82 and the housing 90. More specifically, the annular member 82 and the housing 90 are fitted into the opening 11a. Subsequently, the housing 90 is pressed downward by a rod-shaped pressing member 91 in the circumferential direction with respect to upper surfaces of the annular member 82 and the housing 90 and a contact portion between the annular member 82 and the housing 90. In addition, the pressing member 91 is fixed to the ceiling plate 11 with bolts or the like (not illustrated). As a result, the internal atmosphere of the vacuum container 1 is set to be airtight. In FIG. 5, the annular member 82 is omitted in order to avoid complicating the figure.

As shown in FIG. 6, a protruded portion 92 extending vertically toward the rotary table 2 is formed on the lower surface of the housing 90 to surround the plasma processing region P3 defined below the housing 90 along the circumferential direction. The above-described plasma-processing gas nozzles 33 to 35 are accommodated in a region surrounded by an inner peripheral surface of the protruded portion 92, the lower surface of the housing 90, and the upper surface of the rotary table 2. The protruded portion 92 at the side of base end portions of the plasma-processing gas nozzles 33 to 35 (at the side of an inner wall of the vacuum container 1) is cut out in a substantially arc shape to conform to the outer shapes of the plasma-processing gas nozzles 33 to 35.

As illustrated in FIG. 4, the protruded portion 92 is formed in the circumferential direction on the lower surface of the housing 90 (at the side of the plasma processing region P3). Due to the protruded portion 92, the seal member 11c is not directly exposed to the plasma. That is to say, the seal member 11c is isolated from the plasma processing region P3. Thus, in a case where the plasma tends to diffuse from the plasma processing region P3, for example, toward the side of the seal member 11c, the plasma must pass under the protruded portion 92, which allows the plasma to be deactivated before reaching the seal member 11c.

As illustrated in FIG. 4, the plasma-processing gas nozzles 33 to 35 are provided in the third processing region P3 below the housing 90 and are connected to an argon gas supply source 140, a hydrogen gas supply source 141, an oxygen gas supply source 142, and an ammonia gas supply source 143. In some embodiments, either or both the hydrogen gas supply source 141 and the ammonia gas supply source 143 may be omitted.

Flow rate controllers 130, 131, 132, and 133 are provided between the plasma-processing gas nozzles 33 to 35 and the argon gas supply source 140, the hydrogen gas supply source 141, the oxygen gas supply source 142, and the ammonia gas supply source 143, respectively. Ar, H₂, O₂, and NH₃ gases are supplied to the respective plasma-processing gas nozzles 33 to 35 at a predetermined flow rate ratio (a mixing ratio) from the argon gas supply source 140, the hydrogen gas supply source 141, the oxygen gas supply source 142 and the ammonia gas supply source 143 via the respective flow rate controllers 130, 131, 132, and 133, respectively. The mixing ratio of the Ar, H₂, O₂, and NH₃ gases is determined depending on a region to be supplied. However, as described above, in the case where one of the hydrogen gas supply source 141 and the ammonia gas supply source 143 is provided, the respective flow rate controller (131 or 133) alone may be provided corresponding to the provided one. In some embodiments, for example, mass flow controllers may be used as the flow rate controllers 130 to 133.

In addition, in a case where a single plasma-processing gas nozzle is used a mixed gas of Ar, H₂NH₃, and O₂ gases described above may be supplied to the single plasma-processing gas nozzle.

FIG. 7 is a vertical cross-sectional view of the vacuum container 1 cut in the rotational direction of the rotary table 2. As illustrated in FIG. 7, the rotary table 2 is rotated clockwise during plasma processing. Thus, the Ar gas tends to infiltrate below the housing 90 via a gap between the rotary table 2 and the protruded portion 92 with the rotation of the rotary table 2. Therefore, in order to suppress the Ar gas from infiltrating underneath the housing 90 via the gap, the gas is ejected from underneath the housing 90 with respect to the location of the gap. Specifically, as illustrated in FIGS. 4 and 7, the gas ejection holes 36 of the plasma-processing gas nozzle 33 are arranged so as to face the gap, namely to face the upstream side of the rotational direction of the rotary table 2 in a downwardly-inclined direction. In some embodiments, an angle θ at which the gas ejection holes 36 of the plasma-processing gas nozzle 33 is oriented with respect to the vertical axis may be, for example, about 45 degrees or may be about 90 degrees so as to face the inner peripheral surface of the protruded portion 92, as illustrated in FIG. 7. That is to say, the angle θ at which the gas ejection holes 36 are oriented may be set to fall within a range of to within a range of about 45 to 90 degrees, at which the infiltration of the Ar gas can be appropriately suppressed, depending on the intended use.

FIG. 8 is an enlarged perspective view illustrating the plasma-processing gas nozzles 33 to 35 provided in the plasma processing region P3. As illustrated in FIG. 8, the plasma-processing gas nozzle 33 is a nozzle capable of covering the entire recess 24 where the wafer W is accommodated and capable of supplying the plasma-processing gas to the entire surface of the wafer W. Meanwhile, the plasma-processing gas nozzle 34 is a nozzle that is provided slightly above the plasma-processing gas nozzle 33 while substantially overlapping the plasma-processing gas nozzle 33 and has a length about half that of the plasma-processing gas nozzle 33. In addition, the plasma-processing gas nozzle 35 has a shape that extends from the outer peripheral wall of the vacuum container 1 along the radial direction at the downstream side of the fan-shaped plasma processing region P3 in the rotational direction of the rotary table 2, and is linearly bent so as to conform to the central region C in the vicinity of the central region C. Hereinafter, for the ease of distinction, the plasma-processing gas nozzle 33 covering the entire recess will be referred to as a base nozzle 33, the plasma-processing gas nozzle 34 covering only the outer side of the recess may be referred to as an outer nozzle 34, and the plasma-processing gas nozzle 35 extending to the central region C may be referred to as an axis-side nozzle 35.

The base nozzle 33 is a gas nozzle for supplying the plasma-processing gas to the entire surface of the wafer W. As described with reference to FIG. 7, the base nozzle 33 ejects the plasma-processing gas toward the protruded portion 92 that constitutes the side surface of the plasma processing region P3.

Meanwhile, the outer nozzle 34 is a nozzle for concentratively supplying the plasma-processing gas toward the outer region of the wafer W.

The axis-side nozzle 35 is a nozzle for concentratively supplying the plasma-processing gas toward the central region close to the rotation axis of the rotary table 2 in the wafer W.

In the case where a single plasma-processing gas nozzle is used, the base nozzle 33 alone may be provided.

Next, a Faraday shield 95 of the plasma source 80 will be described in more detail. As illustrated in FIGS. 4 and 5, the Faraday shield 95 as a metal plate which is a conductive plate-like body and is made of, for example, copper, is accommodated in the concaved central portion of the housing 90, and is grounded. The Faraday shield 95 is formed so as to substantially conform to the inner shape of the housing 90. The Faraday shield 95 includes a horizontal surface 95a horizontally fitted along the bottom surface of the housing 90 and a vertical surface 95b extending upward from an outer end of the horizontal surface 95a in the circumferential direction. The Faraday shield 95 may be configured to have, for example, a substantially hexagonal shape in a plan view.

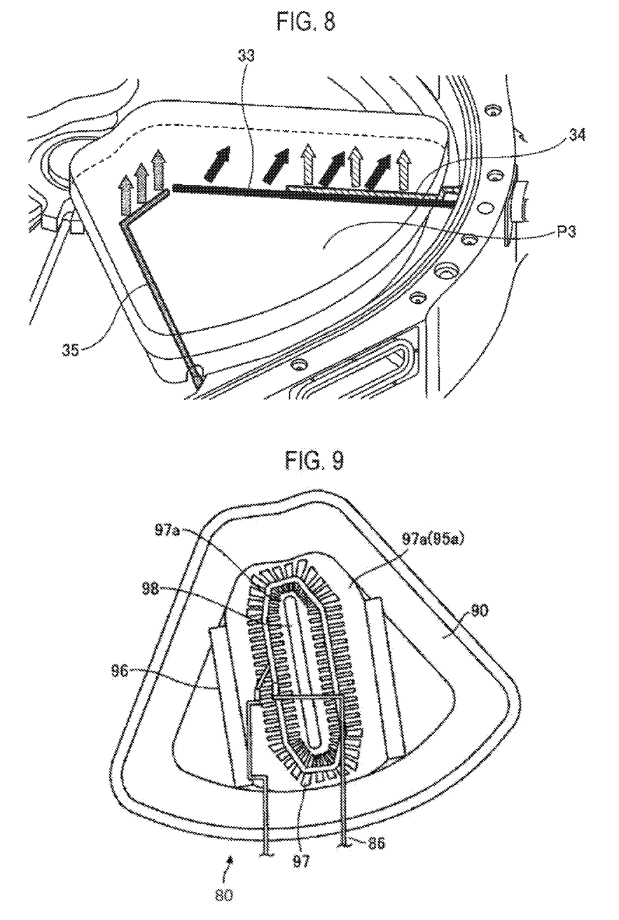

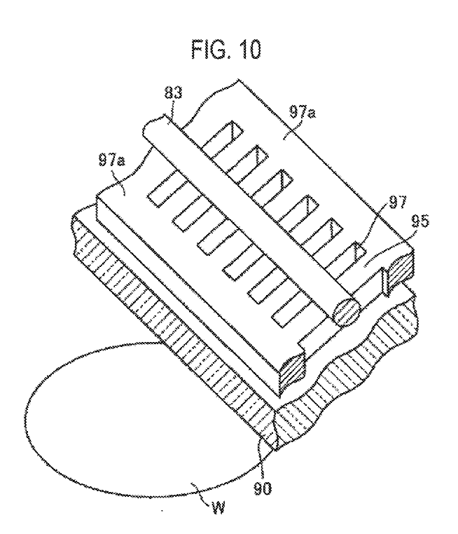

FIG. 9 is a plan view of an example of the plasma source 80, in which the details of the structure of the antenna 83 and the vertically-movable mechanism are omitted. FIG. 10 is a perspective view illustrating a portion of the Faraday shield 95 provided in the plasma source 80.

When viewing the Faraday shield 95 from the rotational center of the rotary table 2, the upper end edges of the Faraday shield 95 at right and left sides extend horizontally to the right and left sides, respectively, thereby forming support portions 96. A frame-shaped body 99 is provided between the Faraday shield 95 and the housing 90 to support the support portions 96 from below and to be supported on each of the flange portions 90a located at the side of the housing 90 close to the central region C and at the side of the outer periphery of the rotary table 2 (see FIG. 5).

When an electric field reaches the wafer W, electric wirings and the like formed inside the wafer W may be electrically damaged in some cases. In order to address such damage, as illustrated in FIG. 10, a plurality of slits 97 is formed in the horizontal plane 95a. The plurality of slits 97 prevents, among an electric field and a magnetic field (electromagnetic fields) generated in the antenna 83, components of the electric field from being directed to the wafer W disposed below the antenna 83, and causes components of the magnetic field to reach the wafer W.

As illustrated in FIGS. 9 and 10, the slits 97 are formed below the antenna 83 in the circumferential direction to extend in a direction orthogonal to the winding direction of the antenna 83. The slits 97 are formed to have a width dimension of about 1/10,000 or less of a wavelength corresponding to the high frequency waves supplied to the antenna 83. In addition, conductive paths 97a formed of a grounded conductor or the like, are arranged on both sides of each of the slits 97 in the longitudinal direction so as to close opened ends of the slits 97 while extending in the circumferential direction. In the Faraday shield 95, an opening 98 is formed in a region that deviates away from the formation region of the slits 97, namely at the center side of the region where the antenna 83 is wound. Through the opening 98, the light-emitting state of the plasma is monitored via the respective region. In FIG. 7, the slits 97 are omitted for the sake of avoiding complexity of illustration, and an example of the formation region of the slits 97 is indicated by a dashed-dotted line.

As illustrated in FIG. 5, an insulating plate 94 formed of, for example, quartz and having a thickness dimension of about 2 mm is stacked on the horizontal plane 95a of the Faraday shield 95 to ensure insulation property between the Faraday shield 95 and the plasma source 80 placed above the Faraday shield 95. That is to say, the plasma source 80 is disposed to cover the interior of the vacuum container 1 (the wafer W on the rotary table 2) through the housing 90, the Faraday shield 95, and the insulating plate 94.

Another component of the film forming apparatus according to this embodiment will be described again.

As illustrated in FIGS. 1 and 2, a side ring 100 serving as a cover body is disposed below the rotary table 2 at the side of the outer periphery of the rotary table 2. As illustrated in FIG. 2, in the upper surface of the side ring 100, exhaust ports 61 and 62 are formed at, for example, two locations to be spaced apart from each other in the circumferential direction. In other words, two exhaust ports are formed in the bottom surface of the vacuum container 1. The exhaust ports 61 and 62 are formed in the side ring 100 at positions corresponding to the two exhaust ports.

In this embodiment, one of the exhaust ports 61 and 62 is referred to as a first exhaust port 61, and the other is referred to as a second exhaust port 62. The first exhaust port 61 is formed at a position close to the separation region D between the first processing gas nozzle 31 and the separation region D defined at the downstream side in the rotational direction of the rotary table 2 with respect to the first processing gas nozzle 31. In addition, the second exhaust port 62 is formed at a position close to the separation region D between the plasma source 80 and the separation region D defined at the downstream side in the rotational direction of the rotary table 2 with respect to the plasma source 80.

The first exhaust port 61 exhausts the first processing gas and the separation gas, and the second exhaust port 62 exhausts the plasma-processing gas and the separation gas. As illustrated in FIG. 1, each of the first exhaust port 61 and the second exhaust port 62 is coupled to, for example, a vacuum pump 64 serving as a vacuum exhaust mechanism via an exhaust pipe 63 in which a pressure adjustment part 65 such as a butterfly valve is installed.

As described above, since the housing 90 is arranged to span from the central region C to the outer periphery of the rotary table 2, the gas flowing from the upstream side of the rotational direction of the rotary table 2 toward the processing region P2 may be restrained by the flow of a gas tending to flow toward the second exhaust port 62 by the housing 90. In order to address such a restraint, a groove-like gas flow path 101 through the gas flows is formed in an upper surface of the side ring 100 at the side of the outer periphery of the housing 90.

As illustrated in FIG. 1, a protruded portion 5 is formed in the central portion of the lower surface of the ceiling plate 11. The protruded portion 5 is formed in ring-like shape in the circumferential direction so as to be continuous with a portion close to the central region C in the convex portion 4 and has a lower surface formed at the same height as the lower surface of the convex portion 4 (the lower ceiling surface 44). A labyrinth structure portion 110 for suppressing various gases from being mixed with each other in the central portion C is arranged above the core part 21 at the side of the rotational center of the rotary table 2 rather than the protruded portion 5.

As described above, the housing 90 is formed to extend up to the position close to the central region C. Thus, the core part 21 supporting the central portion of the rotary table 2 is disposed at the side of the rotational center such that a portion above the rotary table 2 avoids the housing 90. Therefore, various gases are more likely to be mixed with each other at the side of the central region C rather than the side of the outer periphery. Therefore, by forming the labyrinth structure portion 110 above the core part 21, it is possible to secure a gas flow path, thus preventing gases from being mixed with each other.

As illustrated in FIG. 1, a heater unit 7 serving as a heating mechanism is arranged in a space between the rotary table 2 and the bottom portion 14 of the vacuum container 1. The heater unit 7 is configured to heat the wafer W on the rotary table 2, for example, in a range from room temperature to about 700 degrees C. via the rotary table 2. In FIG. 1, a cover member 71a is provided at the lateral side of the heater unit 7. A member 7a is provided to cover the heater unit 7 from the top. In addition, in the bottom portion 14 of the vacuum container 1, a plurality of purge gas supply pipes 73 is provided below the heater unit 7 at multiple locations in the circumferential direction to purge the arrangement space of the heater unit 7.

As illustrated in FIG. 2, a transfer port 15 is formed in the sidewall of the vacuum container 1 to deliver the wafer W between a transfer arm 10 and the rotary table 2. The transfer port 15 is configured to be hermetically opened or closed by a gate valve G.

The delivery of the wafer W is performed at a position where the recess 24 of the rotary table 2 faces the transfer port 15. To do this, lifting pins (not shown) penetrating through the recess 24 to lift up the wafer W from the rear surface of the wafer W and a lifting mechanism (not illustrated) therefor are provided at a location below the rotary table 2, which corresponds to the delivery position.

Further, the film forming apparatus according to this embodiment is provided with a control part 120 including a computer for controlling the entire operation of the apparatus. A memory of the control part 120 stores a program for performing substrate processing to be described later. The program includes a group of steps so as to execute various operations of the apparatus, and is installed on the control part 120 from a storage part 121 which is a storage medium such as a hard disk, a compact disk, a magneto-optical disk, a memory card, a flexible disk or the like.

The control part 120 controls the film forming method according to the embodiment of the present disclosure, which is performed by the film forming apparatus. Specifically, the control part 120 executes a gas supply sequence to create a state in which plasma is likely to be ignited in the plasma processing region P3 in a subsequent operation. The control part 120 controls the valves and the flow rate controllers 130 to 133 connected to the respective plasma-processing gas nozzles 33 to 35, and controls flow rate controllers (not illustrated) connected to the raw material gas nozzle 31 and the oxidizing gas nozzle 32 to perform control for executing a preparation step of such a plasma ignition. Details of the film forming method according to this embodiment will be described later.

### [Film Forming Method]

Hereinafter, the film forming method using the film forming apparatus according to the embodiment of the present disclosure will be described. Examples of a thin film capable of being formed by the film forming method according to this embodiment may include metal oxide films such as TiO₂, ZrO₂, HfO₂, or the like, in addition to a silicon oxide film (SiO₂). In this embodiment, for the sake of convenience in description, an example in which a silicon-containing gas is used as a raw material gas will be described. As described above, oxygen, ozone, water, hydrogen peroxide or the like may be used as the oxidizing gas. In this embodiment, an example in which ozone is used as the oxidizing gas will be described. Various gases may be used as the plasma-processing gas as long as they contain oxygen during modification and contain hydrogen atoms at the end of the modification. In this embodiment, an example in which a mixed gas of argon, oxygen, and hydrogen is used as the plasma-processing gas will be described. As the separation gas, an inert gas such as nitrogen or the like, or a noble gas such as helium, argon or the like may be used. In this embodiment, an example in which argon is used as the separation gas will be described.

First, the wafer W is loaded into the vacuum container 1. When loading a substrate such as the wafer W, the gate valve G is first opened. Then, while rotating the rotary table 2 in an intermittent manner, the wafer W is mounted on the rotary table 2 through the transfer port 15 by the transfer arm 10.

Subsequently, the gate valve G is closed. In a state in which the interior of the vacuum container 1 is kept at a predetermined pressure by the vacuum pump 64 and the pressure adjustment part 65, the wafer W is heated by the heater unit 7 to a predetermined temperature while rotating the rotary table 2. At this time, the Ar gas is supplied as a separation gas from each of the separation gas nozzles 41 and 42. A series of controls described above is performed by the control part 120.

Subsequently, the silicon-containing gas is supplied from the first processing gas nozzle 31, and the ozone gas is supplied from the second processing gas nozzle 32. The plasma-processing gas composed of a mixed gas of argon, oxygen, and hydrogen is also supplied from the plasma-processing gas nozzles 33 to 35 at a predetermined flow rate. In addition to the supply of the plasma-processing gas from the plasma-processing gas nozzles 33 to 35, high frequency power is supplied from the high frequency power supply 85 to the antenna 83 to generate plasma.

In the first processing region P1, the silicon-containing gas is adsorbed onto the front surface of the wafer W with the rotation of the rotary table 2. Subsequently, the silicon-containing gas adsorbed onto the wafer W is oxidized by the ozone gas in the second processing region P2. As a result, one or more molecular layers of a silicon oxide film (SiO₂), which is a thin film component, is formed and deposited on the wafer W.

As the rotary table 2 further rotates, the wafer W reaches the plasma processing region P3 where the silicon oxide film is modified by plasma processing. In the plasma processing region P3, a mixed gas of Ar/O₂/H₂ is supplied as a plasma-processing gas from the base nozzle 33, the outer nozzle 34, and the axis-side nozzle 35. If necessary, with reference to the supply of the mixed gas from the base nozzle 33, in a central axis-side region where the angular velocity is low and an amount of the plasma processing tends to be large, the flow rate of the oxygen may be reduced such that the modification power becomes weaker than that of the mixed gas supplied from the base nozzle 33. In an outer periphery-side region in which the angular velocity is high and an amount of the plasma processing tends to be insufficient, the flow rate of the oxygen may be increased such that the modification power becomes stronger than that of the mixed gas supplied from the base nozzle 33. This makes it possible to appropriately adjust the influence of the angular velocity on the rotary table 2.

In this state, by continuing the rotation of the rotary table 2, the adsorption of the silicon-containing gas onto the front surface of the wafer W, the oxidation of components of the silicon-containing gas adsorbed onto the front surface of the wafer W, and the plasma-based modification of the silicon oxide film as a reaction product, are performed multiple times in this order. That is to say, the film forming process based on an ALD method and the modification process of the formed film are performed multiple times with the rotation of the rotary table 2.

In the film forming apparatus according to this embodiment, the separation regions D are defined between the first and second processing regions P1 and P2 and between the third and first processing regions P3 and P1 along the circumferential direction of the rotary table 2. Therefore, in the separation regions D, the respective gases are exhausted toward the exhaust ports 61 and 62 in the state where the processing gases and the plasma-processing gas are prevented from being mixed with each other.

The film formation process and the modification process as described above are repeated such that the silicon oxide film has a predetermined film thickness. Then, the supply of the silicon containing gas, the ozone gas, and the plasma-processing gas is stopped. Alternatively, the supply of the silicon-containing gas and the ozone gas is stopped, and only the supply of the plasma-processing gas is continued. The reason for this is to form a high-quality silicon oxide film by continuing only the modification process of the silicon oxide film.

Thereafter, in a typical film forming method, the supply of the plasma-processing gas is also stopped, the rotation of the rotary table 2 is stopped, and the processed wafer W is unloaded from the vacuum container 1.

However, in the film forming method according to this embodiment, in the state in which the plasma source 80 is operated, once the film formation process and the modification process are completed, only the supply of the oxygen gas in the plasma-processing gas is stopped and only the argon gas and the hydrogen gas are supplied. At this state, the plasma process is performed. As a result, oxygen adhering to a surface inside the plasma processing region P3 is reduced, which makes it possible to restore the interior of the plasma processing region P3 to a charge neutral state.

That is to say, when the entire process is completed in the state in which the oxygen plasma is supplied to the plasma processing region P3, the process is terminated in the state in which oxygen (also including oxygen radicals) is adhered to surfaces in the plasma processing region P3. In this state, the processed wafer W is unloaded from the vacuum container 1 and a new wafer W to be subjected to the film formation process is loaded into the vacuum container 1. Subsequently, when an attempt is made to ignite the plasma, plasma ignition may be delayed. In other words, during a first-round film formation process, the plasma ignition is performed smoothly. However, the plasma ignition may not be smoothly performed during a second-round film formation process and subsequent processes.

This is presumably because electronegativity of oxygen is extremely high and electron capture ability is also high. It is considered that the state where plasma is likely to be ignited is a state in which charges such as electrons, cations and the like are likely to be generated in a space. Plasma refers to the state in which molecules constituting a gas are ionized to be divided into cations and electrons and the cations and the electrons are in motion, and is gas containing charges particles generated by the ionization. Thus, in the environment in which the charged particles are likely to be generated, plasma is also likely to be generated. That is to say, it is considered that the environment in which the charged particles are likely to be generated is an environment in which the plasma ignition easily occurs.

In the state in which oxygen has adhered to the surfaces in the plasma processing region P3, more specifically, a ceiling surface of the housing 90, an inner peripheral surface of the protruded portion 92 (see FIG. 5) and the like, even if the plasma-processing gas is supplied and the high-frequency power is supplied to the antenna 83 so as to generate plasma discharge, it is considered that the ionized electrons are immediately captured by oxygen on the inner surface, which makes it difficult for the charged particles to be sufficiently accumulated in the plasma processing region P3.

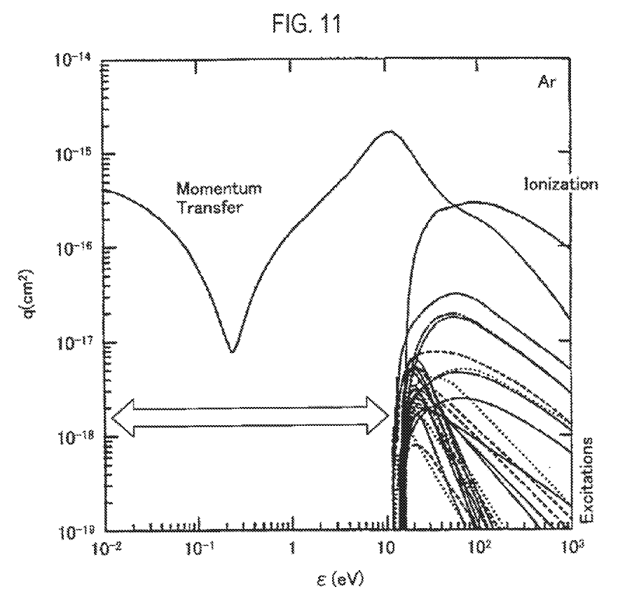

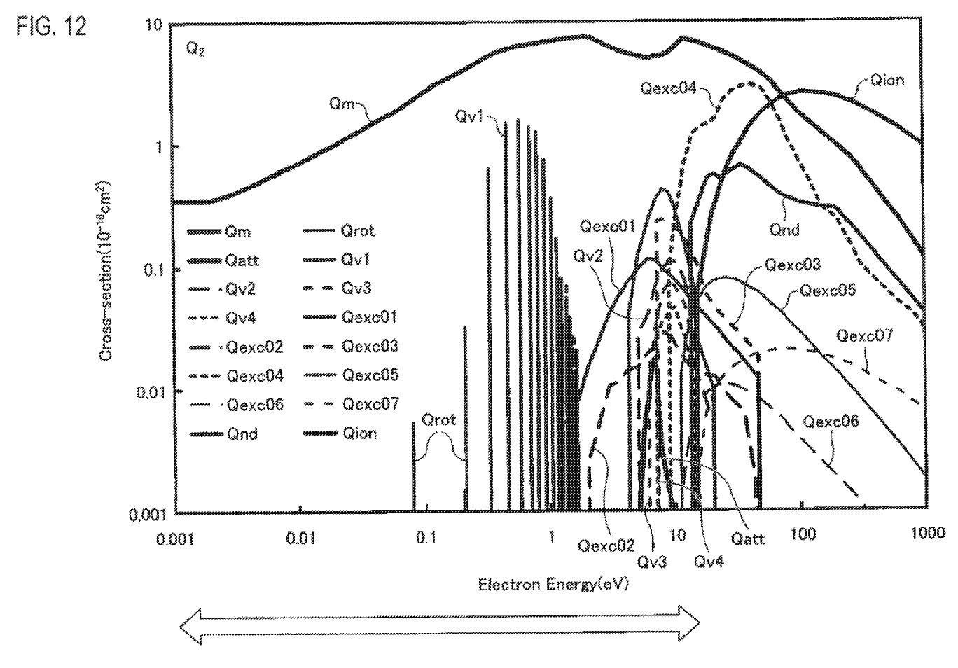

Such a mechanism will be described with reference to FIGS. 11 and 12. FIG. 11 is a diagram showing the ionization electron energy of argon gas. In FIG. 11, the horizontal axis represents the energy of electrons consumed in the ionization of argon gas. In a low energy region of less than 10 eV, electrons are not consumed for ionization. Accordingly, in the low electron energy state at an initial discharge stage, the discharge is not hindered and thus the discharge is likely to occur.

FIG. 12 is a diagram showing the ionization electron energy of oxygen gas. In FIG. 12, the horizontal axis represents the energy of electrons consumed in the ionization of oxygen gas. In a low energy region of less than 10 eV, many reactions in which electrons are consumed (captured) are manifested. Specific reactions include rotation of oxygens (indicated by Qrot), vibration of oxygens (indicated by Qv1 to Qv4), generation of O⁻ due to collision between O₂ and electrons (indicated by Qatt) are observed in the low energy region before ionization (less than 10 eV, around 0.08 to 3 eV). That is to say, it can be seen that in the low electron energy region as in the initial stage of plasma ignition, electrons are likely to be captured by oxygen, and efficiency is very poor when oxygen exists.

From such a viewpoint, in the film forming method according to this embodiment, once the film formation process and the modification process are completed, the hydrogen atom-containing gas is turned into plasma in the state in which plasma is generated, and oxygen and oxygen radicals are reduced with hydrogen plasma and hydrogen radicals. This makes it possible to remove oxygen and oxygen radicals adhering to the surfaces in the plasma processing region P3. Thus, it is possible to restore the state from the state in which electrons are likely to be captured to a neutral normal state, thereby preventing the delay of plasma ignition.

In addition, the plasma ignition delay means that a state where plasma is not ignited continues for 0.1 seconds or more after the high-frequency power is supplied from the high frequency power supply 85 to the antenna 83 (after plasma ignition).

While continuing such a state, when the entire film formation process is finished and the wafer W is unloaded from the vacuum container 1, the plasma processing region P3 stays in the charge neutral state. Thus, when a new wafer W is loaded into the vacuum container 1 where the film formation process is performed, it is possible to ignite plasma without delay.

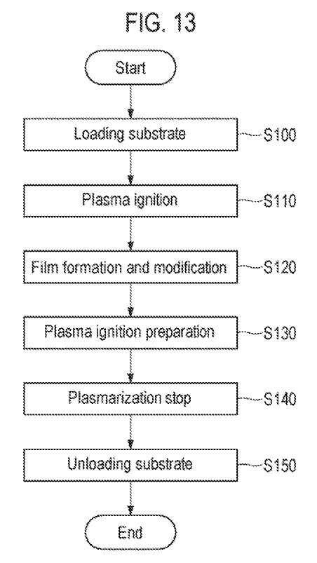

FIG. 13 is a process flowchart of the film forming method according to this embodiment. Details of the process of the film forming method according to this embodiment are as described above. The overall process flow including plasma ignition will be described with reference to FIG. 13. Also, a general description on a gas to be supplied or the like will be given.

In Step S100, a substrate loading step is carried out. Specifically, one or more wafers W is loaded into the vacuum container 1 through the transfer port 15, and is mounted in the respective recess 24 of the rotary table 2. Thereafter, the heating of the interior of the vacuum container 1, the rotation of the rotary table 2, the supply of the separation gas, and the like are performed.

In Step S110, the plasma ignition is performed. Specifically, the plasma-processing gas is supplied from the plasma-processing gas nozzles 33 to 35, and the high-frequency power is supplied from the high frequency power supply 85 to the antenna 83 of the plasma source 80. Simultaneously with the supply of the plasma-processing gas and the high-frequency power or before and after the supply, the raw material gas and the oxidizing gas are supplied from the raw material gas nozzle 31 and the oxidizing gas nozzle 32, respectively.

In Step S120, the rotary table 2 continues to rotate in the state in which the raw material gas, the oxidizing gas, and the plasma-processing gas are being supplied, and the film formation process and the modification process are repeatedly performed. In addition, the film formation process is performed in the raw material gas adsorption region P1 and the oxidation region P2, and the modification process is performed in the plasma processing region P3. In the modification process, oxygen plasma or oxygen radicals are supplied to the oxide film such that the oxide film is densified to have a high density. Therefore, the plasma-processing gas contains at least oxygen gas. By repeating the film formation process and the modification process, the oxide film is deposited on the wafer W while being modified.

When the oxide film has a predetermined film thickness, the supply of the raw material gas and the oxidizing gas is stopped. Only the modification process may be continuously performed as necessary. In the case of continuing only the modification process, the supply of the raw material gas and the oxidizing gas is stopped, and the supply of the plasma-processing gas and the supply of the high-frequency power to the antenna 83 are continued. The supply of the separation gas is also continued.

In Step S130, a plasma ignition preparation step is performed. In the plasma ignition preparation step, in order to reduce and remove oxygens and oxygen radicals adhering to the surfaces in the plasma processing region P3 (the ceiling surface and the inner surface of the housing 90), the supply of the oxygen gas is stopped, and the hydrogen atom-containing gas is supplied while being plasmarized and/or radicalized. Examples of the hydrogen atom-containing gas may include a hydrogen gas, an ammonia gas, and the like. The hydrogen atom-containing gas is intended to include not only a single gas of a substance containing hydrogen atoms, but also a mixture gas. Examples of the hydrogen atom-containing gas may include a gas not containing hydrogen atoms such as an argon gas as long as it does not disturb reduction, in addition to the hydrogen gas and the ammonia gas. In addition, when referring to a single gas of a substance including hydrogen atoms such as hydrogen or ammonia, a hydrogen atom-containing substance or a hydrogen atom-containing substance gas may be referred to distinguish that from the hydrogen atom-containing gas.

In the case where the hydrogen-containing gas such as hydrogen or ammonia is not included in the plasma-processing gas used in the modification process, the hydrogen atom-containing gas is newly supplied to the plasma processing region P3 in the plasma ignition preparation step S130. For example, a plasma-processing gas containing at least one of hydrogen and ammonia is supplied. In this case, as described above, if necessary, the argon gas may be supplied simultaneously with the supply of the plasma-processing gas.

Meanwhile, in the case where the hydrogen gas and/or the ammonia gas are contained in the plasma-processing gas in the modification process, only the supply of the oxygen gas may be stopped. Although only at least one of the hydrogen gas and the ammonia gas is supplied, both may be supplied when it is desired to perform reduction in a short period of time. In the case where both the hydrogen gas and the ammonia gas are supplied but only one of hydrogen and ammonia is contained in the plasma-processing gas during film formation, hydrogen or ammonia, which is not contained in the plasma-processing gas, may be newly additionally supplied. In this manner, the plasma ignition preparation step S130 in the plasma processing region P3 may be performed with an appropriate combination in consideration of components of the plasma-processing gas supplied in the modification process S120.

The plasma ignition step S110 may be performed in a time period of several seconds of about 0.1 seconds to 10 seconds. In experiments conducted by the present inventors, it has been confirmed that when a flow rate of the hydrogen atom-containing substance gas is set to about 100 sccm and when the hydrogen atom-containing substance gas is supplied for about 0.5 seconds, ignition delay does not occur at a subsequent plasma ignition. That is to say, it has been confirmed that the plasma non-ignition state is less than 0.1 second. Meanwhile, it has also been confirmed that when the flow rate of the hydrogen atom-containing substance gas is set to about 45 sccm, a time period of about two seconds is required. Details of the results of the experiments results will be described later.

As described above, by reducing the oxygens and oxygen radicals adhering to the surfaces in the plasma processing region P3 with hydrogen radicals and/or hydrogen plasma, it is possible to prevent occurrence of plasma ignition delay in a subsequent film formation process on a new wafer W and to make the time period of the plasma ignition constant between respective operations.

As described above, the plasma ignition delay means that a state where plasma is not ignited continues for 0.1 seconds or more after the high-frequency power is supplied from the high frequency power supply 85 to the antenna 83 (after plasma ignition).

In step S140, the plasmarization is stopped, and the plasma ignition preparation step is completed. Specifically, the supply of the plasma-processing gas in the plasma ignition preparation step is stopped, and the supply of the high-frequency power to the antenna 83 is stopped.

In step S150, the wafer W which has been subjected to the entire film formation process including the plasma ignition preparation step is unloaded from the vacuum container 1. Specifically, the rotary table 2 is rotated in an intermittent manner. When the wafer W is located to face the transfer port 15. The wafer W is lifted up by the lifting pins and is unloaded from the vacuum container 1 by the transfer arm 10. In this way, one round of film formation process is completed. As described above, the one round of film formation process means a process performed from when the substrate (the wafer W) is loaded into a processing chamber (the vacuum container 1) until when the substrate (the wafer W) that has been subjected to the entire film formation process including the plasma ignition preparation step is unloaded from the processing chamber. The one round of film formation process may be referred to as a one-run process.

In some embodiments, all wafers W (e.g., five or six wafers W) may be unloaded. Further, a transfer process may be performed in which loading and unloading operations are simultaneously performed in such a manner that, each time when one sheet of wafer W is unloaded from a recess 24, a new one is loaded in the respective empty recess 24. In this case, the completion of the previous one-run process and the initiation of a subsequent one-run process may overlap.

After all the subsequent wafers W are loaded into the vacuum container 1, Steps S100 to S150 may be repeated. By performing such a series of processes, it is possible to perform one round of film formation process in continuous and stable manner with a constant plasma ignition time.

As described above, according to the film forming method of this embodiment, it is possible to make the plasma ignition time constant while eliminating the plasma ignition delay each round.

In this embodiment, in the case where a silicon oxide film is formed, various silicon-containing gases may be used as a raw material gas. For example, DIPAS [di-isopropylamino silane], 3DMAS [tris(dimethylamino)silane] gas, BTBAS [bis(tertiarybutylamino)silane], DCS [dichlorosilane], HCD [hexachlorodisilane] or the like may be used as the raw material gas.

In the case of forming a metal oxide film, a metal-containing gas such as TiCl₄ [titanium tetrachloride], Ti(MPD)(THD) [titanium methylpentanedionatbis tetramethylheptanedionato], TMA [trimethylaluminum], TEMAZ [tetrakis(ethylmethylamino)zirconium], TEMHF [tetrakis-ethyl-methyl-amino-hafnium], Sr(THD)₂ [strontium bis tetramethylheptanedionato] or the like may be used as the raw material gas.

As described above, O₂, O₃, H₂O, H₂O₂ or the like may be used as the oxidizing gas. As the plasma-processing gas for modification, various gases may be used as long as they contain oxygen. For example, a mixture gas such as Ar/O₂/H₂, Ar/O₂/NH₃, Ar/O₂/H₂/NH₃ or the like may be used. Further, as the plasma-processing gas for reduction in the plasma ignition preparation step, various gases may be used as long as they include a hydrogen atom-containing substance gas such as a hydrogen gas, an ammonia gas or the like and not include oxygen. For example, a mixture gas such as Ar/H₂, Ar/NH₃, or Ar/H₂/NH₃ may be used.

In the above embodiments, the example in which the oxidizing gas used in the oxidation process and the oxygen used in the modification process are respectively supplied to the different processing regions P2 and P3 has been described. However, both the oxidation and modification processes may be performed in the plasma process performed in the modification process. In this case, in a configuration of the film forming apparatus and the film forming method, the second processing region P2 may be omitted and both the oxidation and modification processes are performed in the third processing region P3. Even in such a case, since the process in the plasma processing region P3 is performed similar to the above, the process flow described with reference to FIG. 13 is applicable as it is.

### EXAMPLES

Next, examples in which the film forming method according to this embodiment is carried out will be described.

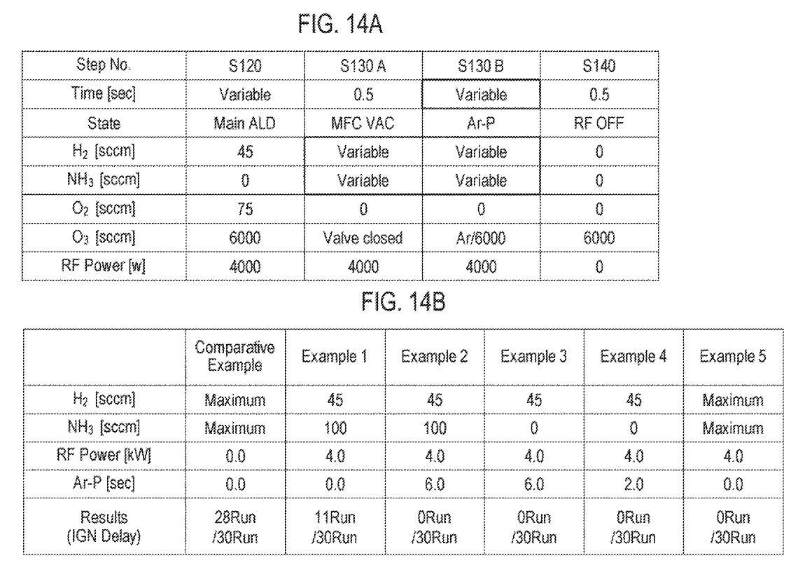

FIGS. 14A and 14B are tables showing the implementation conditions and results of Examples 1 to 4 in which the film forming method according to this embodiment was implemented. The film forming method of Example 1 was performed using the ALD-based film forming apparatus according to the embodiment described with reference FIGS. 1 to 10.

FIG. 14A is a table showing the implementation conditions of a film forming method according to Examples 1 to 5. In FIG. 14A, step number, time, process state, flow rates of hydrogen, ammonia, and oxygen in the plasma processing region P3, and a flow rate of ozone in the oxidation region P2 are shown. The step number corresponds to the number of each step of the process flow illustrated in FIG. 13.

As shown in FIG. 14A, in Step S120 where the film formation process and the modification process are performed, the flow rate of ozone in the oxidation region P2 was set to 6,000 sccm. In the plasma processing region P3, the flow rate of hydrogen was set to 45 sccm and the flow rate of oxygen was set to 75 sccm. No ammonia was supplied in the film formation process and the modification process. The output of the high frequency power supply 85 was set to 4,000 W. The argon gas is an element having little effect on the film formation process and the modification process. With this in mind, the description on the argon gas supplied to the plasma processing region P3 is omitted. Argon was also supplied at a predetermined flow rate.

Steps S130A and 130B correspond to the plasma ignition preparation step. In the plasma ignition preparation process, experiments were conducted by variously changing the flow rates of hydrogen and ammonia. In step S130A, the valve used in supplying the ozone gas in the oxidation region P2 was switched to be closed, and the supply of the ozone gas was stopped. Further, the supply of the oxygen gas in the plasma processing region P3 was stopped. In step S130A, the time was fixed at 0.5 seconds. The output of the high frequency power supply 85 was maintained at 4.000 W.

In step S130B, the supply of the ozone gas in the oxidation region P2 was stopped, and the argon gas was supplied at 6,000 sccm. The flow rates of hydrogen and ammonia in Step S130A were set to become equal respectively to those in Step S30B. The supply amount of the oxygen gas was maintained at zero.

In step S140, the plasmarization was stopped. That is to say, the supply of the high-frequency power from the high frequency power supply 85 to the antenna 83 was stopped, and the supply of all the gases to the plasma processing region P3 was stopped. Then, 30 runs were performed in each of which loading and unloading operations of the wafer W are performed and then a subsequent operation is performed.

FIG. 14B is a table showing specific conditions and results of the plasma ignition preparation step. First, a case where there is no plasma ignition preparation step was taken as a comparison condition, which is regarded as a Comparative example. In this Comparative example, since there is no plasma ignition preparation step, the time in both Steps S130A and S130B is zero and the operation of the plasma source 80 is also stopped. However, the supply of the hydrogen and ammonia gases was continued in a state in which the scales of the flow rate controllers 131 and 133 (FIG. 4) were set to maximum.

As a result, in Comparative example, plasma ignition delay was observed in 28 runs among 30 runs.

In Example 1, 45 sccm of hydrogen and 100 sccm of ammonia were supplied for only 0.5 seconds in step S130A. Step S130B was set to 0 seconds so as not to be performed. In this case, plasma ignition delay was observed in 11 runs among 30 runs. It was confirmed that by providing the plasma ignition preparation step inasmuch as a short period of time of 0.5 seconds, it is possible to reduce the plasma ignition delay compared with Comparative example.

In Example 2, hydrogen was continuously supplied at a flow rate of 45 sccm and ammonia was additionally supplied at 100 sccm. Step S130B was performed for 6 seconds. For the total of 6.5 seconds in both Steps S130A and S130B, hydrogen was supplied at a flow rate of 45 sccm, and ammonia was supplied at a flow rate of 100 sccm. As a result, no plasma ignition delay did occur among 30 runs.

In Example 3, only hydrogen was continuously supplied at a flow rate of 45 sccm, and no additional ammonia was supplied. The time in Step S130B was set to 6 seconds. Therefore, the total time of the plasma ignition preparation step was set to 6.5 seconds. Even in this case, no plasma ignition delay did occur among 30 runs. Thus, good results were obtained.

In Example 4, only hydrogen was continuously supplied at a flow rate of 45 sccm as in Example 3, and no additional ammonia was supplied. The time in Step S130B was shortened to 2 seconds. Therefore, the total time of the plasma ignition preparation step was set to 2.5 seconds. Even in this case, no plasma ignition delay did occur among 30 runs. Thus, good results were obtained. As described above, it was shown in Example 4 that it is possible to effectively prevent the plasma ignition delay merely by continuing the supply of hydrogen only for 2.5 seconds from the film formation and modification processes.

In Example 5, both hydrogen and ammonia were supplied at the maximum scale of the flow rate controllers 131 and 133, namely at flow rates of the upper limit. Alternatively, Step S130B was set to 0 seconds so as not to be provided, and in Step S130A, gases were supplied in a short period of time of 0.5 seconds. Even in this case, no plasma ignition delay did occur among 30 runs. Thus, good results were obtained. As described above, it was shown in Example 5 that even if the plasma ignition preparation step is performed in a short period of time, it is possible to reliably prevent the plasma ignition delay by setting the flow rate of the hydrogen atom-containing substance gas to be very large.

From the results of Examples 4 and 5, it was shown that it is necessary to supply a certain amount of hydrogen plasma or hydrogen radicals in order to reduce oxygens adhering to the surfaces in the plasma processing region P3, and it is possible to choose whether to adjust the amount by time or by flow rate depending on the intended use.

The flow rate of hydrogen in the plasma ignition preparation step may be set to fall within a range of 30 sccm to an infinite value, specifically 45 sccm to an infinite value, more specifically 45 sccm to 200 sccm. Similarly, the flow rate of ammonia in the plasma ignition preparation step may be set to fall within a range of 50 sccm to an infinite value, specifically 100 sccm to an infinite value, more specifically 100 sccm to 200 sccm. The time required for the plasma ignition preparation step may be set to fall within a range of 0.3 to 10 seconds, specifically 0.5 to 8 seconds, more specifically 0.5 to 6.5 seconds. A more specific time may be set to fall within a range of 2.5 to 6.5 seconds.

As described above, according to the film forming apparatus and the film forming method of the above embodiments, it is possible to remove oxygen containing oxygen radicals that adheres to the plasma processing region in a simple and reliable manner in the plasma ignition preparation step, which preventing plasma ignition delay.

In the above embodiments, the rotary table type ALD-based film forming apparatus has been described by way of an example. However, the film forming apparatus and the film forming method according to the above embodiments are suitably applicable to any apparatus as long as it has a plasma processing region defined therein and performs a process of forming an oxide film. For example, the film forming apparatus and the film forming method according to the above embodiments may be suitably applicable to an apparatus that performs chemical vapor deposition (CVD) using plasma, and may also be appropriately applicable to an apparatus and method for performing a film formation process using a susceptor of a type other than the rotary table type, or a wafer boat configured to vertically hold wafers.

According to the present disclosure, it is possible to prevent plasma ignition delay in each operation when a film forming apparatus is successively operated.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
a modification process of modifying an oxide film formed on a substrate using oxygen radicals generated by a plasma source in a predetermined plasma processing region defined within a processing chamber, and
an ignition preparation process of turning an internal state of the predetermined plasma processing region into a state in which plasma is likely to be ignited after the oxide film is formed on the substrate.

2. The film forming method of claim 1, wherein the ignition preparation process includes supplying a hydrogen atom-containing gas into the predetermined plasma processing region in a state in which the plasma is generated, instead of supplying an oxygen gas into the predetermined plasma processing region.

3. The film forming method of claim 2, wherein the hydrogen atom-containing gas is at least one selected from a group consisting of a hydrogen gas and an ammonia gas.

4. The film forming method of claim 3, wherein the hydrogen atom-containing gas further includes an argon gas.

5. The film forming method of claim 4, wherein the modification process is performed by activating a plasma-processing gas including the argon gas, the hydrogen gas, and the argon gas supplied to the predetermined plasma processing region using the plasma source, and
the ignition preparation process is performed by stopping the supply of the oxygen gas of the plasma-processing gas into the plasma processing region and by continuing the supply of the argon gas and the oxygen gas of the plasma-processing gas into the predetermined plasma processing region.

6. The film forming method of claim 1, further comprising: a film formation process, that occurs before the modification process, the film formation process including:
an adsorption process of causing a raw material gas to be adsorbed onto the substrate; and
an oxidation process of oxidizing the raw material gas adsorbed onto the substrate to deposit a molecular layer of the oxide film.

7. The film forming method of claim 6, wherein the substrate is mounted on a rotary table along a circumferential direction, and
wherein a raw material gas adsorption region, an oxidation region, and the predetermined plasma processing region are defined above the rotary table in a mutually spaced-apart relationship with each other along a rotational direction of the rotary table,
the substrate mounted on the rotary table passes through the raw material gas adsorption region, the oxidation region, and the predetermined plasma processing region in a sequential manner by rotating the rotary table multiple times in the rotational direction such that the substrate is repeatedly subjected to the film formation process and the modification process,
the formation of the oxide film is completed when a film thickness of the oxide film reaches a predetermined film thickness, and
subsequently, the ignition preparation process is performed.

8. The film forming method of claim 7, wherein purge gas supply regions to which a purge gas is supplied onto the substrate are defined between the raw material gas adsorption region and the oxidation region and between the predetermined plasma processing region and the raw material gas adsorption region, respectively, and
the film forming method further comprises: purging processes of supplying the purge gas to the purge gas supply regions between the adsorption process and the oxidation process and between the modification process and the adsorption process, respectively.

9. The film forming method of claim 1, wherein the predetermined plasma processing region is a region surrounded by a ceiling surface and a sidewall, and
wherein the plasma source is an inductively-coupled plasma source provided outside the processing chamber above the ceiling surface.

10. The film forming method of claim 1, wherein the oxide film is a silicon oxide film or a metal oxide film.

11. The film forming method of claim 1, further comprising:
a substrate unloading process of unloading the substrate on which the oxide film is formed from the processing chamber;
a loading process of loading a new substrate into the processing chamber; and
a plasma ignition process of igniting the plasma in the predetermined plasma processing region,
wherein the substrate unloading process, the loading process, and the plasma ignition process occur after the ignition preparation process

12. A film forming apparatus comprising:
a processing chamber;
a rotary table provided inside the processing chamber and configured to mount a substrate on an upper surface of the rotary table along a circumferential direction;
a raw material gas supply part configured to supply a raw material gas to the rotary table;
an oxidizing gas supply part provided at a downstream side in a rotational direction of the rotary table and configured to supply an oxidizing gas to the rotary table;
a plasma-processing gas supply part provided at a downstream side in the rotational direction of the rotary table and configured to supply a plasma-processing gas to the rotary table;
a plasma processing region defined to surround the plasma-processing gas supply part from upper and lateral sides of the plasma-processing gas supply part;
a plasma source configured to generate plasma within the plasma processing region; and
a controller configured to control the raw material gas supply part, the oxidizing gas supply part, the plasma-processing gas supply part and the plasma source to execute a control,
wherein the control alternately performs a film formation process of forming an oxide film on the substrate by controlling the raw material gas supply part to supply the raw material gas and controlling the oxidizing gas supply part to supply the oxidizing gas while rotating the rotary table, and a modification process of modifying the oxide film by driving the plasma source and controlling the plasma-processing gas supply part to supply the plasma-processing gas including an oxidizing gas; and after the film formation process and the modification process, performing a plasma ignition preparation process of stopping the supply of the raw material gas and the supply of the oxidizing gas, and controlling the plasma-processing gas supply part to stop supplying an oxygen gas while driving the plasma source and to supply a hydrogen atom-containing gas.
